(19) United States
(12) Patent Application Publication
(10) Pub. No.: US 2025/0298052 A1
(43) Pub. Date: Sep. 25, 2025

(54) STORAGE DEVICE, SENSING DEVICE, AND SENSOR SYSTEM

(71) Applicant: ROHM CO., LTD., Kyoto-shi (JP)

(72) Inventor: Yo YAMASHIRO, Kyoto-shi (JP)

(21) Appl. No.: 19/232,107

(22) Filed: Jun. 9, 2025

Related U.S. Application Data
(63) Continuation of application No. PCT/JP2023/043812, filed on Dec. 7, 2023.

(30) Foreign Application Priority Data
Dec. 16, 2022 (JP) 2022-201027

(51) Int. Cl. G01P 15/125; G01P 15/18; H03K 3/037; H03K 19/21

(52) U.S. Cl. CPC G01P 15/125; G01P 15/18; H03K 3/037; H03K 19/21

(57) ABSTRACT

A storage device includes a first and a second storage portion configured to store data with opposite polarities, and an error sensing portion configured to sense an error if the outputs of the first and second storage portions have the same polarity.

### CROSS-REFERENCE TO RELATED APPLICATIONS

This application is a continuation under 35 U.S.C. § 120 of PCT/JP2023/043812 filed on Dec. 7, 2023, which claims priority Japanese Patent Application No. 2022-201027 filed in Japan on Dec. 16, 2022. The present application likewise claims priority under 35 U.S.C. § 119 to Japanese Application No. 2022-201027, filed Dec. 16, 2022, the entire contents of which are hereby incorporated by reference.

### BACKGROUND OF THE INVENTION

### 1. Technical Field

The invention disclosed herein relates to a storage device and relates also to a sensing device and a sensor system incorporating the same.

### 2. Description of Related Art

Acceleration sensing devices (e.g., see Unexamined Japanese Patent Application Publication No. 2019-49434) are incorporated in electronic vehicle keys. In an electronic vehicle key, for reduced energy consumption, usually only the acceleration sensing device is in operation. In the electronic vehicle key, when the acceleration sensing device senses acceleration associated with a motion of a human carrying the electronic vehicle key, it outputs an interrupt signal to a microcomputer as a host device so that the microcomputer operates. Then the microcomputer in the electronic vehicle key wirelessly communicates with the vehicle to unlock it.

In the electronic vehicle key described above, unless the acceleration sensing device senses a motion of a human carrying the electronic vehicle key, the microcomputer as a host device does not operate. Thus, the electronic vehicle key described above can prevent car theft by relay attack.

### BRIEF DESCRIPTION OF DRAWINGS

FIG. 1 is a diagram showing the configuration of an electronic key according to an embodiment.

FIG. 2 is a diagram showing the configuration of part of a storage device.

FIG. 3 is a diagram showing the relationship between the value of data and the state of an error sensing portion.

FIG. 4 is a timing chart in illustration of the operation of the electronic key according to the embodiment.

### DESCRIPTION OF EMBODIMENTS

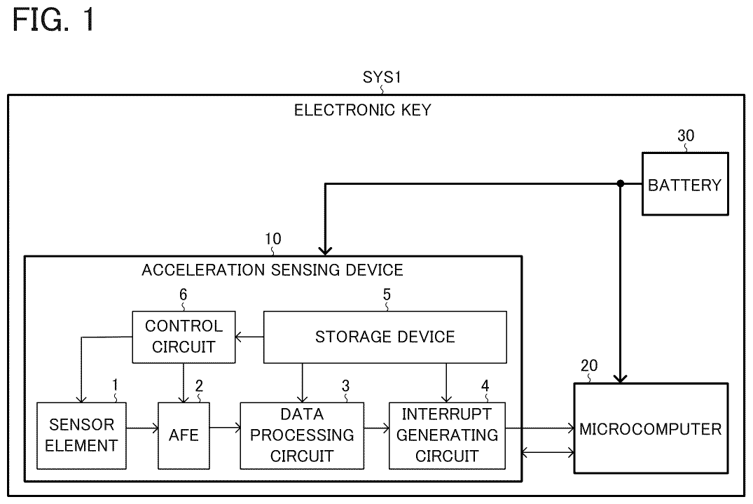

FIG. 1 is a diagram showing the configuration of an electronic key SYS1 according to an embodiment. The electronic key SYS1 is an example of a sensor system including a sensing device and a signal processing device.

The electronic key SYS1 includes an acceleration sensing device 10, a microcomputer 20, and a battery 30. The acceleration sensing device 10 and the microcomputer 20 operates from the output power of the battery 30.

The microcomputer 20 is normally in a sleep state. On receiving an interrupt signal output from the acceleration sensing device 10, the microcomputer 20 wakes from the sleep state into a state where it can wirelessly communicate with a vehicle.

The acceleration sensing device 10 includes a sensor element 1, an AFE 2, a data processing circuit 3, an interrupt generating circuit 4, a storage device 5, and a control circuit 6. The acceleration sensing device 10 is a triaxial acceleration sensor of a capacitive type that can simultaneously measure acceleration along three axes orthogonal to each other. Note that the acceleration that the acceleration sensing device 10 can simultaneously measure need not be acceleration along three axes orthogonal to each other but can instead be acceleration along two axes orthogonal to each other or acceleration along one axis.

The sensor element 1 is an acceleration sensor element of a capacitive type employing MEMS (micro electro mechanical system) technology. The sensor element 1 includes a fixed electrode, a movable electrode, and a spring all made of silicon, for example. With no acceleration acting on the sensor element 1, the distance between the fixed and movable electrodes does not change. On the other hand, when acceleration acts on the sensor element 1, the movable electrode is displaced with respect to the fixed electrode, so that the capacitance between the fixed and movable electrodes changes. In other words, according to the acceleration that acts on the sensor element 1, the capacitance of the sensor element 1 changes.

Note that the sensor element 1 need not be an acceleration sensor element of a capacitive type but can be, for example, one of a piezo-resistive type, a thermal sensing type, or the like. In other words, the sensor element 1 can be any sensor element of which properties change according to acceleration acting on the sensor element 1.

The AFE (analog front end) 2 is connected to the sensor element 1 and outputs an analog signal indicating the change of the capacitance of the sensor element 1. The AFE 2 receives the analog signal indicating the change of the capacitance of the sensor element 1 from the sensor element 1 and outputs it to the data processing circuit 3.

The data processing circuit 3 converts the analog signal indicating the change of the capacitance of the sensor element 1 into a digital signal, performs on the digital signal data adjustment such as gain adjustment and offset adjustment, and senses, based on the digital signal after the data adjustment, acceleration associated with a motion of a human carrying the electronic key SYS1.

When the data processing circuit 3 senses acceleration associated with a motion of a human carrying the electronic key SYS1, the interrupt generating circuit 4 transmits an interrupt signal to the microcomputer 20.

Even without periodic communication with the acceleration sensing device 10, the microcomputer 20 can, by communicating with it on receiving an interrupt signal, recognize the sensing of acceleration associated with a motion of a human carrying the electronic key SYS1 without failure. The omission of periodic communication between the microcomputer 20 and the acceleration sensing device 10 helps reduce the electric power needed for communication in both the microcomputer 20 and the acceleration sensing device 10. In addition, the microcomputer 20 can stay in a sleep state until it receives an interrupt signal, and this helps reduce the electric power consumed by the microcomputer 20.

The storage device 5 is, for example, a shift register and stores settings and the like related to the sensing by the acceleration sensing device 10. The settings related to the sensing by the acceleration sensing device 10 include, for example, what adjustment to perform in the data processing circuit 3, the format of the interrupt signal, how to control the sensor element 1 and the AFE 2, and the like.

The settings related to the sensing by the acceleration sensing device 10 stored in the storage device 5 are used in the data processing circuit 3, the interrupt generating circuit 4, and the control circuit 6.

The control circuit 6 controls the sensor element 1 and the AFE 2.

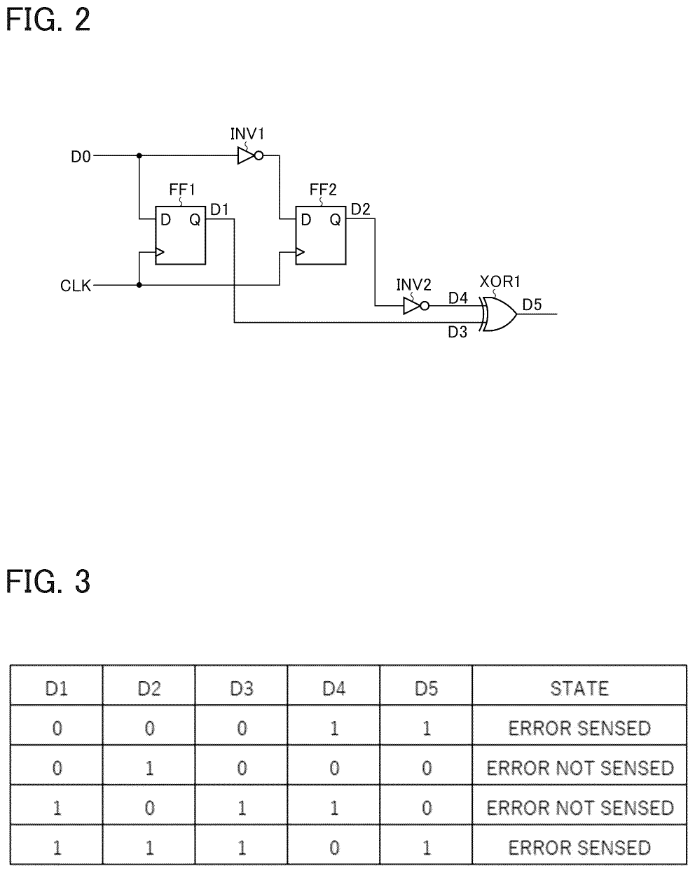

FIG. 2 is a diagram showing the configuration of part of the storage device 5. Of the data stored in the storage device 5, an important piece of data DO is stored in a form converted to two bits as shown in FIG. 2. Data DO can be part or all of the data stored in the storage device 5. The storage device 5 includes as many of the circuits shown in FIG. 2 as the number of pieces of data DO.

The circuit shown in FIG. 2 includes flip-flops FF1 and FF2, inverters INV1 and INV2, and an exclusive-OR gate XOR1.

The flip-flop FF1 stores data DO with an unchanged polarity. The inverter INV1 and the flip-flop FF2 store data DO with an inverted polarity. That is, a first storage portion constituted by the flip-flop FF1 and a second storage portion constituted by the inverter INV1 and the flip-flop FF2 store data DO with opposite polarities. Note that the flip-flops FF1 and FF2 each store the data fed to its data input terminal (D) in synchronization with a clock signal CLK fed to its clock input terminal.

Since the first storage portion constituted by the flip-flop FF1 and the second storage portion constituted by the inverter INV1 and the flip-flop FF2 store data DO with opposite polarities, even if what is stored in the storage device 5 is changed due to an unintended cause such as noise or a surge, they are less likely to behave in the same manner. In other words, even if what is stored in the storage device 5 is changed due to an unintended cause such as noise or a surge, it is likely that, while in one of the first storage portion constituted by the flip-flop FF1 and the second storage portion constituted by the inverter INV1 and the flip-flop FF2, the polarity of the stored data inverts, in the other, the polarity of the stored data does not invert.

An error sensing portion constituted by the inverter INV2 and the exclusive-OR gate XOR1 senses an error when the outputs from the first and second storage portions have the same polarity. In the embodiment, the inverter INV2 receives the output of the second storage portion. Then, the exclusive-OR gate XOR1 outputs the exclusive OR of the outputs of the first storage portion and the inverter INV2. As a modified embodiment, the inverter INV2 can be disposed, instead of between the flip-flop FF2 and the exclusive-OR gate XOR1, between the flip-flop FF1 and the exclusive-OR gate XOR1.

FIG. 3 is a diagram showing the relationship between the value of data and the state of the error sensing portion.

If what is stored in the storage device 5 is not changed, data D1 output from the output terminal (Q) of the flip-flop FF1 and data D2 output from the output terminal (Q) of the flip-flop FF2 have different values. In this case, data D3 fed to the first input terminal of the exclusive-OR gate XOR1 and data D4 fed to the second input terminal of the exclusive-OR gate XOR1 have the same value, and thus data D5 output from the exclusive-OR gate XOR1 has the value of “0.” That is, when no error is being sensed, the error sensing portion constituted by the inverter INV2 and the exclusive-OR gate XOR1 outputs data D5 with the value of “0”.

If what is stored in one of the flip-flops FF1 and FF2 is changed due to an unintended cause such as noise or a surge, data D1 output from the output terminal (Q) of the flip-flop FF1 and data D2 output from the output terminal (Q) of the flip-flop FF2 have the same value. In this case, data D3 fed to the first input terminal of the exclusive-OR gate XOR1 and data D4 fed to the second input terminal of the exclusive-OR gate XOR1 have different values, and thus data D5 output from the exclusive-OR gate XOR1 has the value “1.” That is, when sensing an error, the error sensing portion constituted by the inverter INV2 and the exclusive-OR gate XOR1 outputs data D5 with the value of “1.”

As described above, the storage device 5 can sense a change in what is stored in it due to an unintended cause such as noise or a surge, that is, it can sense an error.

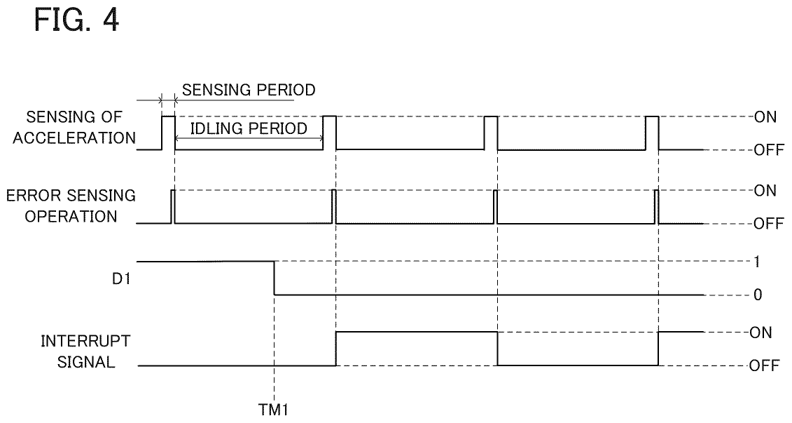

FIG. 4 is a timing chart in illustration of the operation of the electronic key SYS1.

The acceleration sensing device 10 performs intermittent sensing operation in which it repeats a sensing period and an idling period. In the sensing period, in which a high accuracy clock generator (not shown in FIG. 1) incorporated in the acceleration sensing device 10 operates, the acceleration sensing device 10 operates based on the clock signal output from the high accuracy clock generator. In the idling period, in which a low accuracy clock generator (not shown in FIG. 1) incorporated in the acceleration sensing device 10 operates, the acceleration sensing device 10 counts an idling period based on the clock signal output from the low accuracy clock generator.

The error sensing portion constituted by the inverter INV2 and the exclusive-OR gate XOR1 operates during the sensing period described above. This allows the use of the clock signal output from the high accuracy clock generator as the clock signal CLK fed to the flip-flops FF1 and FF2.

The interrupt generating circuit 4 outputs an interrupt signal to the microcomputer 20 not only when the acceleration associated with a motion of a human carrying the electronic key SYS1 is sensed by the data processing circuit 3 but also when an error is sensed by the error sensing portion constituted by the inverter INV2 and the exclusive-OR gate XOR1. In other words, the microcomputer 20 receives the sensing result of the acceleration sensing device 10 as well as the error sensing result.

On receiving an interrupt signal, the microcomputer 20 checks what is stored in the storage device 5 to judge which interrupt signal it has received, an interrupt signal ascribable to the sensing result of the acceleration sensing device 10 or an interrupt signal ascribable to the error sensing result of the acceleration sensing device 10. If the microcomputer 20 judges that it has received an interrupt signal ascribable to the error sensing result of the acceleration sensing device 10, it resets the acceleration sensing device 10. In other words, on receiving the error sensing result of the acceleration sensing device 10, the microcomputer 20 resets the acceleration sensing device 10. This allows the acceleration sensing device 10 to restore the normal state. Thus, it is possible to improve the reliability of the electronic key SYS1 without increasing the energy consumption.

The microcomputer 20 can sense the interrupt signal by various methods including rising-edge sensing, falling-edge sensing, high-level sensing, and low-level sensing. Thus, the interrupt generating circuit 4 has to generate an interrupt signal that matches the interrupt signal sensing method employed by the microcomputer 20. If, however, the settings related to the generation of an interrupt signal are changed due to an unintended cause such as noise or a surge, an interrupt signal may not be generated so as to match the interrupt signal sensing method employed by the microcomputer 20. To avoid that, if the error sensing portion constituted by the inverter INV2 and the exclusive-OR gate XOR1 senses an error, the acceleration sensing device 10 outputs a toggle signal that alternates between high and low levels to the signal processing device. For example, if, as shown in FIG. 4, data D1 output from the output terminal (Q) of the flip-flop FF1 changes due to an unintended cause such as noise or a surge at time TM1, in the error sensing operation carried out after that, the interrupt generating circuit 4 outputs as an interrupt signal a toggle signal that alternates between high and low levels.

A toggle signal that alternates between high and low levels includes all of a rising edge, a falling edge, a high level, and a low level. Thus, using as an interrupt signal a toggle signal that alternates between high and low levels allows the microcomputer 20 to sense the interrupt signal regardless of the interrupt signal sensing method employed by the microcomputer 20. Thus, the microcomputer 20 can reliably realize the error sensing result.

### OTHERS

The invention can be implemented in any manner other than as described specifically above, with various modifications made without departing from the spirit of the invention. The above embodiment should be understood to be in every aspect illustrative and not restrictive. The scope of the invention is defined not by the description of the embodiment given above but by the appended claims and encompasses any modifications made within a scope equivalent in significance to those claims.

For example, while the sensing device used in the embodiment described above is an acceleration sensing device that senses acceleration, the sensing device incorporating the storage device can be any sensing device other than an acceleration sensing device. In addition, the storage device can be incorporated in any devices, systems, apparatuses, and the like other than sensing devices.

### NOTES

To follow are notes on what is disclosed herein, of which a specific example of configuration is described above as an embodiment.

According to one aspect of the present disclosure, an storage device (5) according to the present disclosure includes a first storage portion (FF1) and a second storage portion (INV1, FF2) configured to store data with opposite polarities and an error sensing portion (INV2, XOR1) configured to sense an error if outputs of the first and second storage portions have the same polarity (a first configuration).

In the storage device according to the first configuration, the error sensing portion can include an inverter (INV2) configured to receive one of the outputs of the first and second storage portions and an exclusive-OR gate (XOR1) configured to output the exclusive-OR of the other of the outputs of the first and second storage portions and the output of the inverter (a second configuration).

According to another aspect of the present disclosure, a sensing device (10) includes a sensor element (1) and the storage device according to the first or second configuration described above (a third configuration).

In the sensing device according to the third configuration, the sensing device can be configured to perform intermittent sensing operation in which it repeats a sensing period and an idling period, and the error sensing portion can be configured to operate during the sensing period (a fourth configuration).

According to yet another aspect of the present disclosure, a sensor system (SYS1) includes the sensing device according to the third or fourth configuration and a signal processing device (20) configured to receive a sensing result of the sensing device and an error sensing result (a fifth configuration).

In the sensor system according to the fifth configuration, the signal processing device can be configured to reset the sensing device on receiving the error sensing result (a sixth configuration).

In the sensor system according to the fifth or sixth configuration, the sensing device can be configured to output, if the error sensing portion senses an error, a toggle signal that alternates between high and low levels to the signal processing device (a seventh configuration).

What is claimed is:

1. A storage device comprising:
a first storage portion and a second storage portion configured to store data with opposite polarities; and
an error sensing portion configured to sense an error if outputs of the first and the second storage portions have a same polarity.

2. The storage device according to claim 1, wherein
the error sensing portion includes:
an inverter configured to receive one of the outputs of the first and second storage portions; and
an exclusive-OR gate configured to output an exclusive-OR of another of the outputs of the first and second storage portions, and an output of the inverter.

3. A sensing device comprising:
a sensor element; and
the storage device according to claim 1.

4. The sensing device according to claim 3, wherein
the sensing device is configured to perform intermittent sensing operation in which the sensing device repeats a sensing period and an idling period, and
the error sensing portion operates during the sensing period.

5. A sensor system comprising:
the sensing device according to claim 3; and
a signal processing device configured to receive a sensing result of the sensing device and an error sensing result.

6. The sensor system according to claim 5, wherein
the signal processing device is configured to reset the sensing device on receiving the error sensing result.

7. The sensor system according to claim 5, wherein
the sensing device is configured to output, if the error sensing portion senses an error, a toggle signal that alternates between high and low levels to the signal processing device.
